(19) United States
(12) Patent Application Publication
(10) Pub. No.: US 2015/0110143 A1
(43) Pub. Date: Apr. 23, 2015

(54) ADJUSTABLE IMPEDANCE LASER DRIVER

(71) Applicant: Xtera Communications, Inc., Allen, TX (US)

(72) Inventors: GERHARD WILLEM VAN LOCHEM, Pretoria (ZA); STEPHEN MICHAEL WEBB, Gravesend (GB)

(21) Appl. No.: 14/200,770

(22) Filed: Mar. 7, 2014

Related U.S. Application Data
(60) Provisional application No. 61/780,534, filed on Mar. 13, 2013.

(51) Int. Cl. H01S 5/042

(52) U.S. Cl. CPC H01S 5/042
USPC 372/38.03; 372/38.04

(57) ABSTRACT

An assembly that includes a laser diode and a driver circuit that operates to give the assembly an adjustable impedance. The driver circuit adjusts impedance by repeatedly alternating between two operational phases. In one operational phase, current is primarily or fully supplied through the laser diode using a first current path being from the first supply node, to the laser diode, and into the second supply node. In the other operational phase, current is supplied through the laser diode using a recirculating second current path. The current through the laser diode increases during the first operational phase, and decays during the second operational phase. For a given applied voltage level between the first and second supply nodes, the duty cycle of the first and second operational phases may be adjusted so that the current through the laser diode is approximately a target current.

### CROSS-REFERENCE TO RELATED APPLICATIONS

The present application claims priority under 35 U.S.C. 119(e) to U.S. provisional application Ser. No. 61/780,534 filed Mar. 13, 2013, which provisional patent application is incorporated herein by reference in its entirety.

### BACKGROUND

Fiber-optic communication networks serve a key demand of the information age by providing high-speed data between network nodes. Fiber-optic communication networks include an aggregation of interconnected fiber-optic links. Simply stated, a fiber-optic link involves an optical signal source that emits an optical signal into an optical fiber, the optical signal carrying information. Due to principles of internal reflection, the optical signal propagates through the optical fiber until it is eventually received into an optical signal receiver. If the fiber-optic link is bi-directional, information may be optically communicated in reverse typically using a separate optical fiber.

Fiber-optic links are used in a wide variety of applications, each requiring different lengths of fiber-optic links. For instance, relatively short fiber-optic links may be used to communicate information between a computer and its proximate peripherals, or between a local video source (such as a DVD or DVR) and a television. On the opposite extreme, however, fiber-optic links may extend hundreds or even thousands of kilometers when the information is to be communicated between two network nodes.

Long-haul and ultra-long-haul optics refers to the transmission of light signals over long fiber-optic links on the order of hundreds or thousands of kilometers. Typically, long-haul optics involves the transmission of optical signals on separate channels over a single optical fiber, each channel corresponding to a distinct wavelength of light using principles of Wavelength Division Multiplexing (WDM) or Dense WDM (DWDM).

Transmission of optical signals over such long distances using WDM or DWDM presents enormous technical challenges, especially at high bit rates in the gigabits per second per channel range. Significant time and resources may be required for any improvement in the art of high speed long-haul and ultra-long-haul optical communication. Each improvement can represent a significant advance since such improvements often lead to the more widespread availability of communications throughout the globe. Thus, such advances may potentially accelerate humankind's ability to collaborate, learn, do business, and the like, with geographical location becoming less and less relevant.

### BRIEF SUMMARY

At least one embodiment described herein relates to an assembly that includes a laser diode and an electrical current supply circuit (e.g., a driver circuit). The driver circuit operates such that the assembly has an adjustable impedance. As an example only, the impedance of the assembly may be adjusted such that its impedance is more closely matched with a supply impedance. For instance, in the case of a long haul repeater, the repeater impedance may be more closely matched with the line impedance used to deliver power to the optical repeater.

Rather than rely on a variable resistor to provide variable impedance, the driver circuit operates to alternate between a first operational phase and a second operational phase when a voltage is applied between a first supply node and a second supply node. In the first operation phase, current is at least dominantly supplied through the laser diode using a first current path being from the first supply node, directly or indirectly, to the laser diode. The first current path continues from the laser diode, directly or indirectly, to the second supply node. In the second operational phase, current is at least dominantly supplied through the laser diode using a recirculating second current path. The current through the laser diode increases during the first operational phase, and decays during the second operational phase.

For a given applied voltage level between the first and second supply nodes, the duty cycle of the first and second operational phases may be adjusted so that the current through the laser diode is approximately a target current. In some embodiments, a current preservation mechanism, such as an inductor, may be placed in an overlapping portion of the first and second current paths so as to have more refined control over the current through the laser diode.

The principles described herein permit for impedance control to be accomplished at greater efficiency. This is an important advantage when delivering electrical power to remote locations. For instance, suppose that the assembly was in a submarine optical repeater. Such a repeater may be many kilometers away from where power is initially provided. Accordingly, electricity within the repeater itself is at a premium. The improved efficiencies allows the repeater to be powered using less power and/or allows that power to be directed towards other purposes, such as providing Raman amplification to the repeater, to thereby improve the bandwidth of the repeater.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

In order to describe the manner in which the above-recited and other advantages and features can be obtained, a more particular description of various embodiments will be rendered by reference to the appended drawings. Understanding that these drawings depict only sample embodiments and are not therefore to be considered to be limiting of the scope of the invention, the embodiments will be described and explained with additional specificity and detail through the use of the accompanying drawings in which:

FIG. 1 illustrates an assembly that includes a laser diode and a driver that supplies electrical power to the laser diode;

FIG. 2 illustrates an environment that includes a controller controlling multiple assemblies, each assembly structured like the assembly of FIG. 1 to drive a corresponding laser diode;

FIG. 3 illustrates an assembly that represents an example of the assembly of FIG. 1, although the controller(s) are not shown;

FIG. 4 illustrates a flowchart of a method for operating a driver circuit that drives a laser diode;

FIG. 5 illustrates a graph that expresses principles of maximizing power efficiency in the case of a 60 watt repeater;

FIG. 6 illustrates an example implementation of an asynchronous embodiment of FIG. 3; and

FIG. 7 schematically illustrates an example optical communications system in which the principles described herein may be employed.

### DETAILED DESCRIPTION

In accordance with embodiments described herein, an assembly is described that includes a laser diode and a driver circuit that operates to give the assembly an adjustable impedance. The driver circuit adjusts impedance by repeatedly alternating between two operational phases. In one operational phase (called a “first” operational phase), current is primarily or fully supplied through the laser diode using a first current path being from the first supply node, to the laser diode, and into the second supply node. In the other operational phase (called a “second” operational phase), current is supplied through the laser diode using a recirculating second current path.

The current through the laser diode increases during the first operational phase, and decays during the second operational phase. For a given applied voltage level between the first and second supply nodes, the duty cycle of the first and second operational phases may be adjusted so that the current through the laser diode is approximately a target current. A current preservation mechanism, such as an inductor, may be placed in an overlapping portion of the first and second current paths so as to have more refined control over the current through the laser diode.

The principles described herein permit for impedance control to be accomplished at greater efficiency. Impedance matching and efficient power delivery are important advantages when considering delivering electrical power to remote locations.

For instance, suppose that the assembly was in a submarine optical repeater. In that case, the power is delivered over a long electrical conductor that is perhaps tens, hundreds, or even thousands of kilometers in length. Thus, the impedance of the power delivery cable may vary greatly as the precise distance (and thus impedance) of the electrical conductor might not be predetermined By allowing the assembly to have an adjustable impedance, the impedance of the assembly may be made to more closely match the impedance of the electrical conductor, whatever the impedance of the electrical conductor might be.

Furthermore, electricity within the repeater itself is at a premium given the electrical losses that occur over the long stretch of the electrical conductor. The improved efficiencies allows the repeater to be powered using less power and/or allows that power to be directed towards other purposes, such as providing Raman amplification to the repeater, to thereby improve the bandwidth of the repeater.

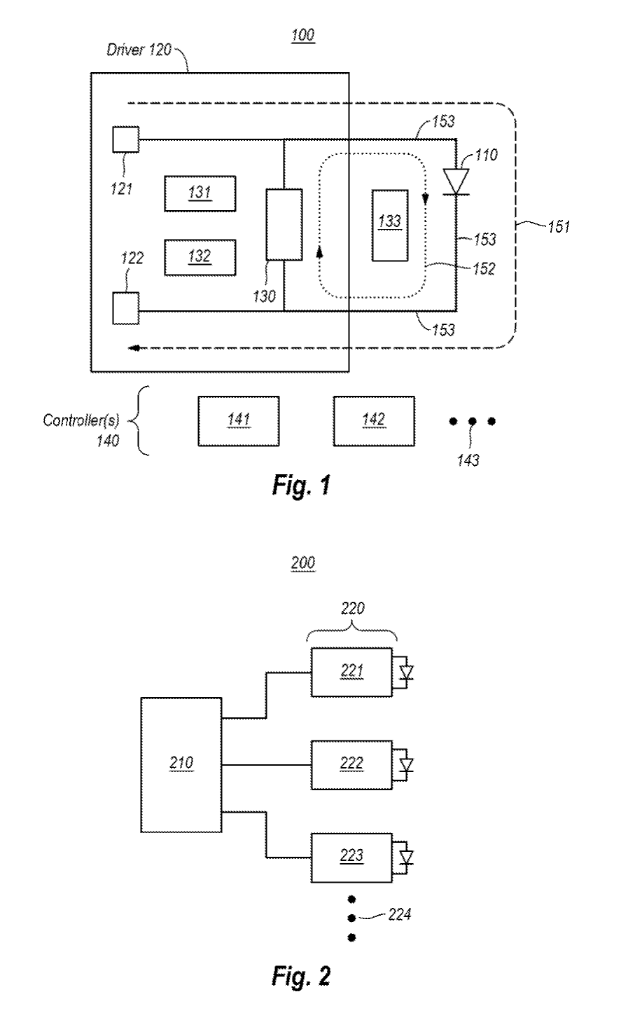

FIG. 1 illustrates an assembly 100 that includes a laser diode 110 and an electrical current supply circuit (also referred to herein as a “driver” 120) that supplies electrical power to the laser diode. Although not required, the assembly 100 may perhaps be a circuit that is on an integrated circuit or on a single circuit board. The voltage drop across the laser diode 110 is relatively stable when the laser diode 110 is saturated in a state that emits light. An example voltage drop across the laser diode is perhaps 2.5 volts, though the principles described herein are not limited to the precise rated voltage drop across the laser diode. In general, the voltage drop across the laser diode 110 will be referenced herein as “V”.

The driver 120 provides current to the laser diode during operation when a voltage (hereinafter referred to as “VS”) is applied between a first supply node 121 and a second supply node 122 of the driver 120. Element 130 permits the voltage VS to be maintained by preventing the supply nodes 121 and 122 from being shorted to each other. The amount of current that is to flow through the laser diode should also be relatively stable. An example of a rated current that might flow through a laser diode is, for example, 400 mA (or 0.4 amps). However, the principles described herein are not limited to the desired amount of current to flow through the laser diode 110. In general, the rated current to flow through laser diode will be referenced herein as “I”.

The voltage VS that is applied across the supply nodes 121 and 122 may be very different than the voltage drop across the laser diode (V). During operation, the driver 120 repeatedly alternates between a first operational phase 131 and a second operational phase 132. These operational phases 131 are illustrated abstractly in FIG. 1. In one embodiment, the voltage VS may be provided to similar driver circuits 120 in serial and or in parallel.

During the first operational phase, current is at least dominantly supplied through the laser diode using a first current path 151 being from the first supply node 121, directly or indirectly, to the laser diode 110, the first current path 151 continuing from the laser diode 110, directly or indirectly, to the second supply node 122. In this first operational phase 131, the current through the laser diode 110 increases. In this description and in the claims, current is “at least dominantly supplied” through a component along a current path when the current that travels along the entire current path either entirely passes through the component, or at least the majority of the current that passes through the component is current that travels along the entire current path. Here, however, it is preferred that during the first operational phase 131, the current passing through the laser diode 110 is entirely supplied along the first current path 151.

During the second operational phase 132, current is at least dominantly supplied through the laser diode using a recirculating current path 152. In this recirculating current path 152, the current flows in a recirculating motion through the laser diode 110 and clockwise as illustrated by the dotted recirculation arrow 152. The first current path 151 and the second current path 152 overlap somewhat to define an overlapping portion 153 (see the more thick-lined portion of the assembly 100 labeled as 152). The laser diode 110 resides within the overlapping portion 153 so that the laser diode 110 receives current along the first current path 151 when the driver 120 is operating in the first operational phase 131, and receives current along the second current path 152 when the driver 120 is operating in the second operational phase 132. Since most (or all) of the current is supplied by a power source in the first operational phase 131, and most (or all) of the current is merely recirculating in the second operational phase 132, the current passing through the laser diode 110 increases during the first operational phase 131, and decays during the second operational phase 132.

Although there are no circuit elements (other than the laser diode 110) illustrated as being within the current paths 151 or 152, there may be other circuit elements within one or both of the current paths. For instance, a current momentum preservation mechanism 133 is only abstractly represented in FIG. 1. The current momentum preservation mechanism 133 is provided in the overlapping portion 153 of the first current path 151 and the second current path 152. Thus, the current preservation mechanism 133 slows the increase in the current supplied through the laser diode 110 during the first operational phase 131, and slows the decay in the current supplied through the laser diode 110 during the second operational phase 132.

During the first operational phase 131, the current through the laser diode 110 will increase from slightly below the target current to slightly above the target current, at which point the driver 120 switches to the second operational phase 132. During the second operational phase 132, the current through the laser diode 110 will decay from slightly above the target current to slightly below the target current, at which point the driver 120 switches to the first operational phase 131. This process repeats. Thus, so long the driver 120 repeatedly switches between the first and second operational phases 131 and 132 at a high enough frequency, the current through the laser diode 110 will hover closely around a target current.

The duty cycle D1 of the first operational cycle 131 will depend on the supply voltage VS supplied across the supply nodes 121 and 122 approximately according the following equation 1:

D1=V/VS (1)

For instance, suppose that the diode voltage is 2.5 volts, and the diode current is 0.4 amps (resulting in a power of 1 watt). If the voltage supply VS were 10 volts, the duty cycle of the first operational phase would be 25% (or 2.5 volts/10 volts). If the voltage supply VS were 5 volts, the duty cycle of the first operational phase would be 50% (or 5 volts/10 volts). Thus, the driver 120 is operational for a wide variety of supply voltages VS. In one embodiment, the duty cycle D2 of the second operational phase is merely the unitary complement of the duty cycle D1 of the first operational phase. In other words, the sum of the first and second duty cycles (D1+D2) is equal to unity (1). However, the principles of the present invention do not preclude the use of further operational phases.

The assembly 100 allows the power in the system to be efficiently used. For instance, assuming 100 percent efficiency, the power supplied through the laser diode 110 should be the same as the power supplied by the voltage source, regardless of the current supplied by the voltage source. Thus, suppose that the current supplied through the 2.5 volt laser diode was 0.4 amps (for 1 watt of total power). The power supplied by a 10 volt supply voltage should be 0.1 amps (10 volts×0.1 amps=1 watt). Likewise, the power supplied by a 5 volt supply voltage should be 0.2 amps (5 volts×0.2 volts=1 watt). Though the assembly allows for improved power efficiency, the efficiency still may fall short of 100 percent. But approximately speaking, by adjusting the duty cycle D1, the power supplied by the driver 120 remains the same while adjusting the current. This has the effect of adjusting the impedance of the assembly 100.

This assembly may be especially useful in cases where there is significant source impedance, as might be the case, for example, should the power be supplied remotely to the assembly 100. For instance, perhaps a line conductor (e.g., a power cable) of several hundred kilometres is providing power from a terrestrial location to a laser driver assembly (perhaps within a submarine repeater) that is operating in a submarine environment.

The maximum power theorem states that the source and load impedance have to be the same to achieve maximum power transfer. In the context of powering a repeater, the power cable impedance (i.e., the source impedance in a repeater environment) is relatively fixed at approximately 1 Ω/km. Accordingly, the principles described herein allow the assembly impedance (i.e., the repeater impedance) to be adjusted thereby allowing a match between source and load impedances in a submarine environment, regardless of what the actual voltage levels are that are received at the repeater. The efficient use of power at the assembly 100, the ability to do adjust the impedance of the assembly 100, and along with the tremendous cost of supplying power over remote distances, make the assembly particularly advantageous in powering remotely located assemblies, such as an assembly in a submarine or remotely located terrestrial repeater.

A controller 141 control a duty cycle of the first and second operational phases so as to control an amount of current flowing through the laser diode 110. In embodiments in which the voltage supply VS, the efficiency of the driver 120, and the efficiency of the laser diode 110 are relatively stable, the duty cycle D1 of the first operational phase (and hence the duty cycle D2 of the second operational phase) may also be relatively constant. In this case, perhaps the controller affixes the duty cycle D1 of the first operational phase based on a configuration setting. However, to afford flexibility, the controller 141 may control the duty cycle based on a measured light output of the laser diode 110. Thus, if the voltage supply VS, the efficiency of the driver 120, and/or the efficiency of the laser diode 110 were to change over time, the controller 141 would respond with an appropriate adjustment to the duty cycle D1.

In FIG. 1, there are actually multiple controllers 140 illustrated, although not required. A second controller 142 (illustrated as a dashed box) controls the duty cycle D1 as a backup to the first controller 141. Other controllers may also be present as further backups are represented by the ellipses 143. Such redundancy allows the assembly 100 to continue operating, even when one of the controllers becomes inoperative. In a submarine environment, it may take some time to be able to repair a repeater. Thus, the ability to continue operation, despite partial failure, is valuable as it provides the opportunity for the assembly 100 to continue operating while repairs are scheduled.

FIG. 2 illustrates an environment 200 that includes a controller 210 controlling multiple assemblies 220, each assembly structured and described as described above for the assembly 100 of FIG. 1 to drive a corresponding laser diode. For instance, assembly 221 may be structured as described for assembly 100 of FIG. 1 and include the driver 120, the corresponding laser diode 110, and the controller(s) 140. The assemblies 220 are illustrated as including three such assemblies 221, 222 and 223, though the vertical ellipses 224 represents flexibility in the number of assemblies, from as few as one to as many as enumerable. In one embodiment, the current is provided to the assemblies 220 in series.

In addition to the controller 210, each assembly 221, 222, 223 may have their own controller, as described in FIG. 1 with respect to the controller(s) 140. In that case, the first operational phase and the second operational phase of each assembly need not be synchronized. Alternatively, the first and second operational phase of each of the assemblies may perhaps be more centrally controlled by the controller 210.

Alternatively or in addition, the controller 210 may communicate with each assembly's controller to indirectly control the duty cycle of each driver. For instance, if the measured light from the assembly 221 were to decline, the controller 210 might respond by instructing the assemblies 222 and/or 223 to increase their light output. In the case of a configuration setting affixing the duty cycle, the controller 210 may change that configuration setting for the assemblies 222 and/or 223. In the case of a controller for each assembly, dynamically adjusting the duty cycle based on measured light output, the controller 210 may instruct the assembly-specific controller(s) to change the desired light output for that assembly. Thus, should an assembly and/or diode fail, the controller 210 may encourage a relatively stable light output by adjusting the intensity of light output for the other laser diodes. By providing multiple levels of redundancy, the reliability of the environment 200 is quite strong. For instance, each of the assemblies 221, 222 and 223 may have multiple controllers (see controller 140 of FIG. 1). Thus, if one controller (e.g., controller 141) ceases operation, the other controller (e.g., controller 142) continues operating the assembly. As another layer of redundancy even should one or more of the assemblies 220 fail or reduce power, the remaining assemblies may be instructed by controller 210 to increase power to stabilize optical output. Again, this provides redundancy which is especially valuable when the assembly is in remote and/or difficult to access locations.

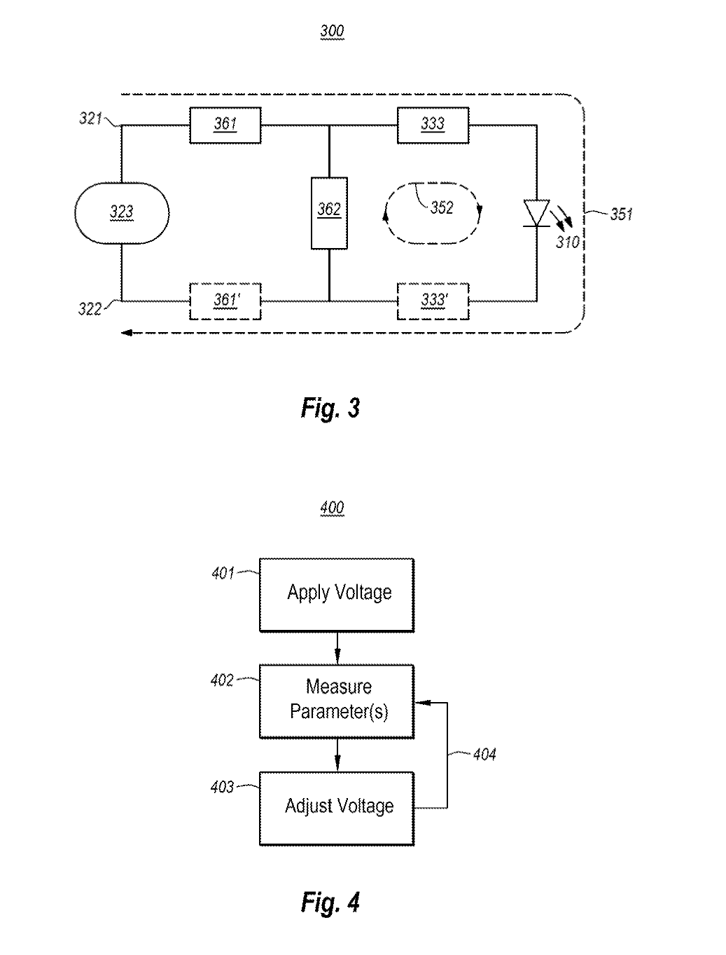

FIG. 3 illustrates an assembly 300 that represents an example of the assembly 100 of FIG. 1, although the controller(s) 140 are not shown. The voltage source 323 provides power between first and second supply nodes 321 and 322 (which represent examples of the first and second supply nodes 121 and 122 of FIG. 1). The laser diode 310 is an example of the laser diode 110 of FIG. 1. The first current path 351 (representing an example of the first current path 151), and the second current path 352 (representing an example of the second current path 152) are also shown.

An inductor 333 is placed in the overlapping portion of the current paths, and represents an example of the current momentum preservation mechanism 133 of FIG. 1. Other components and/or network of components may also operate to preserve current, and may be used as the current momentum preservation mechanism 133 without departing from the inventive principles described herein.

As illustrated the inductor 333 (the solid-lined box) may be placed between the first supply node 321 and the laser diode 310 in the first current path 351, but still in the overlapping portion. Alternatively or addition, an inductor 333′ (the dashed-lined box) may be placed between the second supply node 322 and the laser diode 311 in the first current path 351, but still in the overlapping portion.

A switch (also called herein a “first” switch) is positioned in the first current path 351, but not in the overlapping portion. For instance, as illustrated, the first switch 361 (the solid-lined box) may be placed between the first supply node 321 and the laser diode 310 in the first current path 351, but not in the overlapping portion. Alternatively, the first switch 361′ (the dashed-lined box) may be placed between the second supply node 322 and the laser diode 310 in the first current path 351, but not in the overlapping portion. The first switch 361 (and/or switch 361′) is closed during the first operational phase 131 allowing current to flow along the first current path 351, and is open during the second operational phase 132, preventing or inhibiting current from flowing from the voltage supply 323.

The assembly 300 also includes a component 362 that is positioned in the second current path 352, but not in the overlapping portion. The component 362 allows current to recirculate during the second operational phase 132, but prevents or inhibits current from flowing through the component 362 during the first operational phase 131.

In a synchronous example, the component 362 is a second switch that is opened during the first operational phase 131, but closed during the second operational phase. Such a configuration may achieve power efficiencies as high as 95 percent or even higher. Alternatively, in an asynchronous embodiment, the component 362 may be another diode that allows current to flow upwards in FIG. 3 when the diode is forward-biased, but inhibits current from flowing downwards in FIG. 3 when the diode is reverse-biased. The use of a diode as component 362 does cause the diode to consume power. Thus, the asynchronous embodiment (in which a diode is used for component 362) may be of somewhat less efficiency than the synchronous embodiment (in which a synchronized switch is used for the component 362). However, the asynchronous embodiment is still likely much more efficient than simply using a varistor to adjust the current supplied to the laser diode, in accordance with the conventional technique.

In operation, during the first operational phase 131, the switch 361 is closed, and the component 362 does not allow significant current to flow (either because it is an open switch in the synchronous embodiment, or a reverse-biased diode in the asynchronous embodiment). Thus, in the first operational phase 131, current is supplied to the laser diode 310 from the voltage source 323 along the first current path 351. During the second operational phase 132, the switch 361 is open, but the component 362 does allow current to flow upwards (either because it is a closed switch, or because it is a forward-biased diode). Thus, the current flows along the recirculating current path 352 during the second operational phase 132.

FIG. 4 illustrates a flowchart of a method 400 for operating a driver circuit (such as the driver circuit 120) that drives a laser diode (such as the laser diode 110). In one embodiment, the method 400 may be performed in order to impedance match the assembly 100 with the source (e.g., a power cable in the case of the assembly being in a remote optical repeater).

First, an initial voltage is applied between the first and second supply nodes (e.g., supply nodes 121 and 122) of the driver circuit (act 401). Note that in order to provide a particular supply voltage to the driver circuit remotely, since there will be voltage loss in the line conductor (e.g., the power cable), a much higher voltage may have to be applied to the line conductor in order to account for such line losses. A parameter of the system is then measured (act 402). The applied voltage is then adjusted (act 403) and the parameter re-measured (act 402) until the parameter achieves its desired range. This repeating is represented by arrow 404. As described above, such adjustment of the applied voltage to the assembly 100 will cause a corresponding change to the duty cycle of the first operational phase 131 of the assembly 100, thereby adjusting the impedance of the assembly. Thus, the applied voltage may be adjusted in order to achieve the desired assembly impedance. In one embodiment, the applied voltage is adjusted until 70, 80, 90, or 95 percent impedance matching between the source (e.g., the power cable) and the load (e.g., the repeater) is achieved.

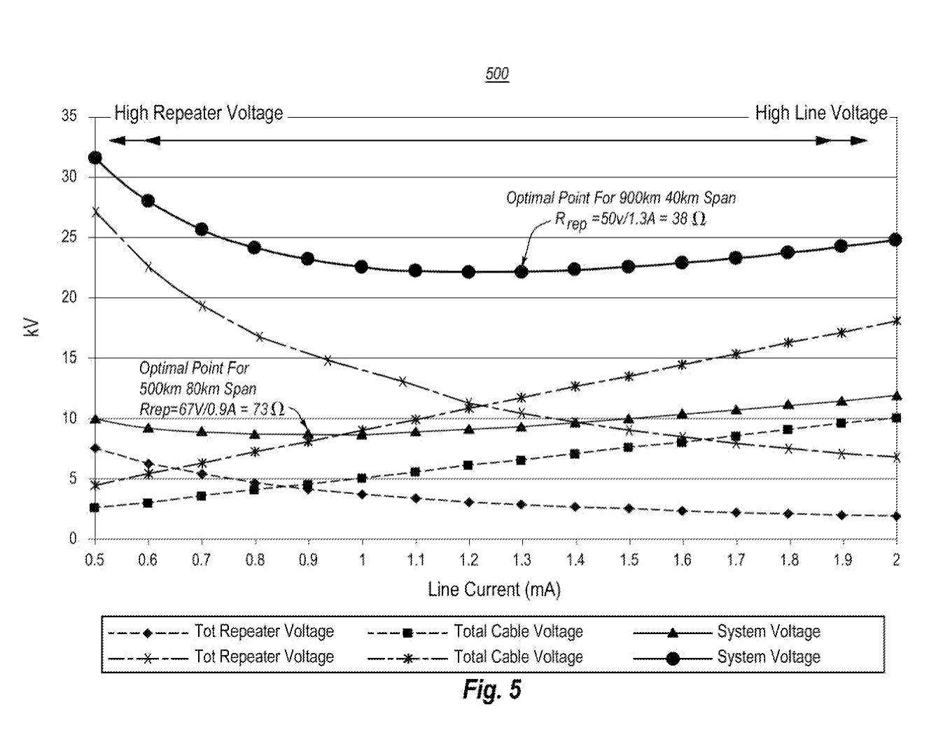

FIG. 5 illustrates a graph 500 that expresses principles of maximizing power efficiency in the case of a 60 watt repeater. The line current (the current applied to the power cable) is represented on the horizontal axis. The line voltage (the voltage applied to the power cable) is represented on the vertical axis. The optimal applied voltage and current will depend on the system. For an example 9000 km system with a 40 km span between repeaters, the impedance of the repeater is adjusted to be 38 ohms with a voltage applied to the repeater of 50 volts, and with a line current of 1.3 amps. In an example 5000 km system with an 80 km span between repeaters, the impedance of the repeater is adjusted to be 73 ohms with a voltage applied to the repeater of 67 volts, and with a line current of 0.9 amps. Thus, different systems have different impedance to achieve balanced impedance and thus maximize power efficiency. The principles described herein allow the assembly (e.g., repeater) impedance to be thus adjusted, and is thus flexibility applied to a variety of different systems. In FIG. 5, the solid lines represent the system voltage in the two example systems. The other four lines represent the component repeater voltage and cable voltage for each of the two systems (see legend).

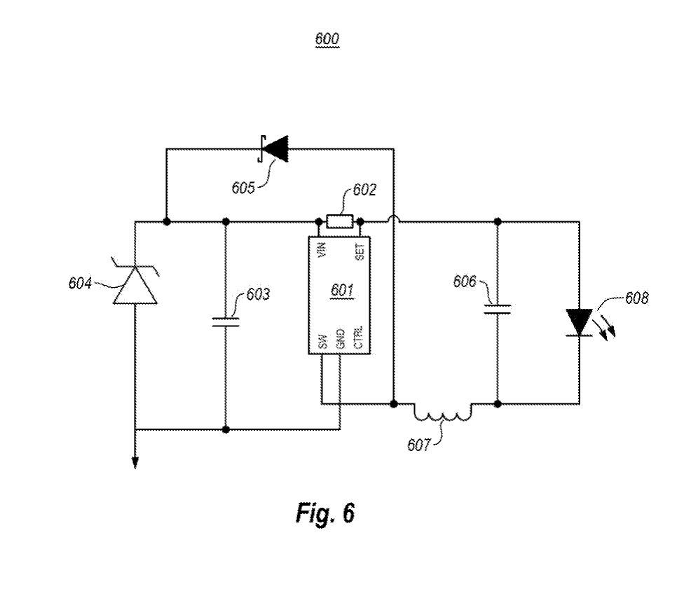

FIG. 6 illustrates an example implementation 600 of the asynchronous embodiment of FIG. 3. The zener diode 604 in combination with the capacitor 603 represent the voltage source 323. The inductor 607 represents and example of the inductor 333 of FIG. 3. The diode 608 represents an example of the laser diode 310 of FIG. 3. The zener diode 605 represents an example of the component 362 of FIG. 3. The capacitor 606 is used for smoothing and filtering the current supplied to the laser diode 608. The controller 601 represents an example of the switch 361 of FIG. 3, and the controller 141 of FIG. 1. The resistor 602 is used to measure current flowing through the laser diode. The component 601 may be, for example, part AL8805 provided by Diodes Inc. Such a component 601 receives an instruction as to the amount of current that should flow through the laser diode, and the component 601 correspondingly adjusts the duty cycle of the first operational phase to achieve that current. In one embodiment, there are two components 601 in parallel.

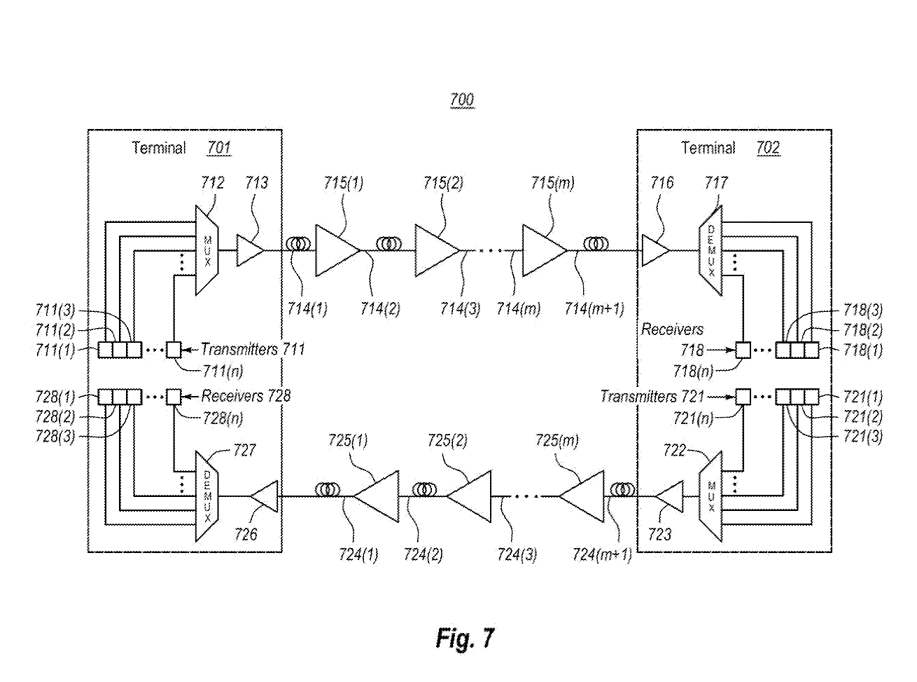

FIG. 7 schematically illustrates an example repeatered optical communications system 700 in which the principles described herein may be employed. Specifically, the assembly 700 (or a series combination of such assemblies) may be used in any of the repeaters. For instance, the system 200 may be included within one or more or all of the repeaters of the optical communications system 700. In that case, perhaps all of the assemblies 210 are coupled in series, and perhaps under the control of a controller 210 (while perhaps also having their own controllers as described above).

In the optical communications system 700, information is communicated between terminals 701 and 702 via the use of optical signals. For purposes of convention used within this application, optical signals travelling from the terminal 701 to terminal 702 will be referred to as being “eastern”, whereas optical signals traveling from the terminal 702 to the terminal 701 will be referred to as being “western”. The terms “eastern” and “western” are simply terms of art used to allow for easy distinction between the two optical signals traveling in opposite directions. The use of the terms “eastern” and “western” does not imply any actual geographical relation of components in FIG. 7, nor to any actual physical direction of optical signals. For instance, terminal 701 may be geographical located eastward of the terminal 702, even though the convention used herein has “eastern” optical signals traveling from the terminal 701 to the terminal 702.

In one embodiment, the optical signals are Wavelength Division Multiplexed (WDM) and potentially Dense Wavelength Division Multiplexed (DWDM). In WDM or DWDM, information is communicated over each of multiple distinct optical channels called hereinafter “optical wavelength channels”. Each optical wavelength channel is allocated a particular frequency for optical communication. Signals that fall within the particular frequency will be referred to as respective optical wavelength signals. Accordingly, in order to communicate using WDM or DWDM optical signals, the terminal 701 may have “n” optical transmitters 711 (including optical transmitters 711(1) through 711(n), where n is a positive integer), each optical transmitter for transmitting over a corresponding eastern optical wavelength channel. Likewise, the terminal 702 may have “n” optical transmitters 721 including optical transmitters 721(1) through 721(n), each also for transmitting over a corresponding western optical wavelength channel. The principles described herein are not limited, however, to communications in which the number of eastern optical wavelength channels is the same as the number of western optical wavelength channels. Furthermore, the principles described herein are not limited to the precise structure of the each of the optical transmitters. However, lasers are an appropriate optical transmitter for transmitting at a particular frequency. That said, the optical transmitters may each even be multiple laser transmitters, and may be tunable within a frequency range.

As for the eastern channel for optical transmission in the eastern direction, the terminal 701 multiplexes each of the eastern optical wavelength signals from the optical transmitters 711 into a single eastern optical signal using optical multiplexer 712, which may then be optically amplified by an optional eastern optical amplifier 713 prior to being transmitted onto a first fiber link 714(1).

There are a total of “m” repeaters (labeled 715 for the eastern repeaters and 725 for the western repeaters) and “m+1” optical fiber links (labeled 714 for the eastern fiber links and 724 for the western fiber links) between the terminals 701 and 702 in each of the eastern and western channels. However, there is no requirement for the number of repeaters in each of the eastern and western channels to be equal. In a repeatered optical communication system, “m” would be one or greater. Each of the repeaters, if present, may consume electrical power to thereby amplify the optical signals.

The eastern optical signal from the final optical fiber link 714(m+1) is then optionally amplified at the terminal 702 by the optional optical amplifier 716. The eastern optical signal is then demultiplexed into the various wavelength optical wavelength channels using optical demultiplexer 717. The various optical wavelength channels may then be received and processed by corresponding optical receivers 718 including receivers 718(1) through 718(n).

As for the western channel for optical transmission in the western direction, the terminal 702 multiplexes each of the western optical wavelength signals from the optical transmitters 721 (including optical transmitters 721(1) through 721(n)) into a single western optical signal using the optical multiplexer 722. The multiplexed optical signal may then be optically amplified by an optional western optical amplifier 723 prior to being transmitted onto a first fiber link 724(m+1). If the western optical channel is symmetric with the eastern optical channel, there are once again “m” repeaters 725 (labeled 725(1) through 725(m)), and “m+1” optical fiber links 724 (labeled 724(1) through 724(m+1)).

The western optical signal from the final optical fiber link 724(1) is then optionally amplified at the terminal 701 by the optional optical amplifier 726. The western optical signal is then demultiplexed using optical demultiplexer 727, whereupon the individual wavelength division optical channels are received and processed by the receivers 728 (including receivers 728(1) through 728(n)). Terminals 701 and/or 702 do not require all the elements shown in optical communication system 700. For example, optical amplifiers 713, 716, 723, and/or 726 might not be used in some configurations. Furthermore, if present, each of the corresponding optical amplifiers 713, 716, 723 and/or 726 may be a combination of multiple optical amplifiers if desired.

Often, the optical path length between repeaters is approximately the same. The distance between repeaters will depend on the total terminal-to-terminal optical path distance, the data rate, the quality of the optical fiber, the loss-characteristics of the fiber, the number of repeaters (if any), the amount of electrical power deliverable to each repeater (if there are repeaters), and so forth. However, a typical optical path length between repeaters (or from terminal to terminal in an unrepeatered system) for high-quality single mode fiber might be about 50 kilometers, and in practice may range from 30 kilometers or less to 100 kilometers or more. That said, the principles described herein are not limited to any particular optical path distances between repeaters, nor are they limited to repeater systems in which the optical path distances are the same from one repeatered segment to the next.

The optical communications system 700 is represented in simplified form for purpose of illustration and example only. The principles described herein may extend to much more complex optical communications systems. The principles described herein may apply to optical communication systems in which there are multiple fiber pairs, each for communicating multiplexed WDM optical signals. Furthermore, the principles described herein also apply to optical communications in which there are one or more branching nodes that split one or more fiber pairs and/or optical wavelength channels in one direction, and one or more fiber pairs and/or optical wavelength channels in another direction.

Accordingly, the principles described herein provide for an assembly that drives a laser diode efficiently while providing for the adjustment of the impedance of the assembly. Although not limited to a repeatered environment, the assembly may be included within a submarine or terrestrial repeater, and permit customized impedance matching appropriate for the optical system.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An assembly comprising:
a laser diode; and
an electrical current supply circuit configured to provide current to the laser diode during operation when a voltage is applied between a first supply node and a second supply node of the electrical current supply circuit, the electrical current supply circuit configured to, during operation, repeatedly alternate between a first operational phase and a second operational phase,
wherein during the first operational phase, current is at least dominantly supplied through the laser diode using a first current path being from the first supply node, directly or indirectly, to the laser diode, the first current path continuing from the laser diode, directly or indirectly, to the second supply node, wherein the current through the laser diode increases during the first operational phase, and
wherein during the second operational phase, current is at least dominantly supplied through the laser diode using a recirculating second current path, wherein the current through the laser diode decays during the second operational phase, wherein the first and second current paths have an overlapping portion, and the laser diode is within the overlapping portion.

2. The assembly in accordance with claim 1, wherein the assembly is an optical repeater.

3. The assembly in accordance with claim 2, wherein the optical repeater is a submarine optical repeater.

4. The assembly in accordance with claim 2, wherein the optical repeater is a terrestrial optical repeater.

5. The assembly in accordance with claim 1, further comprising:
a current momentum preservation mechanism configured to slow the increase in the current supplied through the laser diode during the first operational phase, and configured to slow the decay in the current supplied through the laser diode during the second operational phase.

6. The assembly in accordance with claim 5, wherein the current momentum preservation mechanism comprises an inductor placed in the overlapping portion of the first and second current paths.

7. The assembly in accordance with claim 6, wherein the inductor is placed between the first supply node and the laser diode in the first current path, but still in the overlapping portion.

8. The assembly in accordance with claim 6, wherein the inductor is placed between the second supply node and the laser diode in the first current path, but still in the overlapping portion.

9. The assembly in accordance with claim 6, further comprising a switch positioned in the first current path, but not in the overlapping portion.

10. The assembly in accordance with claim 9, wherein the switch is a first switch, the assembly further comprising a second switch positioned in the second current path, but not in the overlapping portion,
wherein during the first operational phase, the first switch is closed, and the second switch is open, allowing the dominant current in the laser diode to flow along the first current path through the first switch,
wherein during the second operational phase, the first switch is open, and the second switch is closed, allowing the dominant current in the laser diode to flow along the second current path through the second switch.

11. The assembly in accordance with claim 9, wherein the laser diode is a first diode, the assembly further comprising:
a second diode positioned in the second current path, but not in the overlapping portion, wherein the second diode is positioned to be reverse-biased during the first operational phase, but to be forward-biased during the second operational phase.

12. The assembly in accordance with claim 1, further comprising:
a controller configured to control a duty cycle of the first and second operational phases so as to control an amount of current flowing through the laser diode.

13. The assembly in accordance with claim 12, wherein the controller controls the duty cycle based on a measured light output of the laser diode.

14. The assembly in accordance with claim 12, wherein the controller controls the duty cycle based on a configuration setting.

15. The assembly in accordance with claim 12, wherein controller is a first controller, the assembly further comprising:
a second controller configured to control a duty cycle of the first and second operational phases as a backup to the first controller.

16. The assembly in accordance with claim 1, wherein
the laser diode is a first laser diode,
the electrical current supply circuit is a first driver circuit,
the overlapping portion is a first overlapping portion,
the assembly further comprising:
a second laser diode;
a second driver circuit configured to provide current to the second laser diode during operation when a voltage is applied between a first supply node and a second supply node of the second driver circuit, the second driver circuit configured to, during operation, repeatedly intermit between a first operational phase and a second operation phase,
wherein during the first operational phase of the second driver circuit, current is at least dominantly supplied through the second laser diode using a first current path of the second driver circuit being from the first supply node of the second driver circuit, directly or indirectly, to the second laser diode, the first current path of the second driver circuit continuing from the second laser diode, directly or indirectly, to the second supply node of the second driver circuit, wherein the current through the second laser diode increases during the first operational phase of the second driver circuit, and
wherein during the second operational phase of the second driver circuit, current is at least dominantly supplied through the second laser diode using a recirculating second current path of the second driver circuit, wherein the current through the second laser diode decays during the second operational phase of the second driver circuit, wherein the first and second current paths of the second driver circuit have a second overlapping portion, and the second laser diode is within the second overlapping portion.

17. The assembly in accordance with claim 16, wherein the first operational phase of the first driver circuit is not synchronized with the first operational phase of the second driver circuit.

18. The assembly in accordance with claim 16, further comprising:
a controller that at least indirectly controls the duty cycle of the first driver circuit and the second driver circuit.

19. The assembly in accordance with claim 18, wherein if measured light from the first laser diode were to decline, the controller would at least indirectly control the duty cycle of the second driver circuit such that light emitted by the second laser diode increases.

20. A method for operating a driver circuit that drives a laser diode,
an act of applying a voltage between a first supply node and a second supply node of the driver circuit, wherein the driver circuit operates intermittently between a first operational phase and a second operational phase, wherein during the first operational phase, current is at least dominantly supplied through the laser diode using a first current path being from the first supply node using the applied voltage, directly or indirectly, to the laser diode, the first current path continuing from the laser diode, directly or indirectly, to the second supply node using the applied voltage, wherein the current through the laser diode increases during the first operational phase, wherein during the second operational phase, current is at least dominantly supplied through the laser diode using a recirculating second current path, wherein the current through the laser diode decays during the second operational phase, wherein the first and second current paths have an overlapping portion, and the laser diode is within the overlapping portion; and
an act of adjusting the voltage applied between the first and second supply nodes.

21. The method in accordance with claim 20, wherein the act of applying is performed by performing an act of applying a larger voltage from a source that is separated from the laser diode by at least 30 kilometers of a line conductor.

22. The method in accordance with claim 21, wherein the laser diode and the driver circuit are part of an optical repeater, wherein the act of adjusting is performed until at least 70 percent impedance matching is obtained between the impedance of the line conductor and the impedance of the optical repeater.

23. The method in accordance with claim 21, wherein the laser diode and the driver circuit are part of an optical repeater, wherein the act of adjusting is performed until at least 90 percent impedance matching is obtained between the impedance of the line conductor and the impedance of the optical repeater.

24. The method in accordance with claim 21, wherein the act of applying a larger voltage from a source is performed from a terrestrial location, and wherein the driver circuit is at a submarine location.

25. The method in accordance with claim 20, wherein the act of adjusting the voltage applied between the first and second supply nodes causes an adjustment in a duty cycle of the first operational phase and the second operational phase.
